(19) United States
(12) Patent Application Publication
(10) Pub. No.: US 2006/0157447 A1
(43) Pub. Date: Jul. 20, 2006

(54) Method and apparatus for forming surface, magnetic head and method of manufacturing the same

(75) Inventors: Yoshiaki Ito, Shatin (HK); Takeshi Nakada, Shatin (HK); Kunihiro Ueda, Shatin (HK); Masao Yamaguchi, Tokyo (JP)

Correspondence Address: GREENBLUM & BERNSTEIN, P.L.C., 1950 ROLAND CLARKE PLACE, RESTON, VA, 20191, US

(73) Assignee: SAE Magnetics (H.K.) Ltd., Hong Kong (HK)

(21) Appl. No.: 11/332,215

(22) Filed: Jan. 17, 2006

(30) Foreign Application Priority Data
Jan. 18, 2005 (JP) 2005-9943

(51) Int. Cl. B44C 1/22; H01L 21/306

(52) U.S. Cl. 216/63; 156/345.24; 216/22

(57) ABSTRACT

It is to manufacture uniform and high-quality structural bodies which face no quality changes due to mechanical process. There is provided a surface forming apparatus that comprises a surface forming device for performing surface forming process to a prescribed structural body, wherein the surface forming device is an irradiation device that irradiates, to the structural body, an energy beam with a prescribed irradiation energy, which can be irradiated in a specific direction.

### BACKGROUND OF THE INVENTION

1. Field of the Invention

The present invention relates to a method and an apparatus for forming a surface and, particularly, to a method and an apparatus for forming a surface, which perform surface forming process without applying mechanical polishing. Further, the present invention relates to a structural body and a magnetic head manufactured by performing the surface forming process and to a manufacturing method of the same.

2. Description of the Related Art

Recently, there has been an remarkable improvement in the recording density of a hard disk drive (referred to as “HDD” hereinafter), and a magnetoresistive element is used as a magnetic head for reproducing data from the magnetic disk with high recording density. For example, there is a magnetic head part using a giant magnetoresistive element (GMR element) or a tunnel junction magnetoresistive element (TMR element) as the magnetoresistive element.

In general, the above-described magnetic head is roughly in a cuboid shape, which is constituted of a magnetic head slider part (main body part) for forming an air bearing surface for allowing a magnetic disk to be floated, and a magnetic head element part (thin-film layered part) that constitutes a recording part and a reproduction part including the above-described magnetoresistive element part formed at the end of the magnetic head slider part.

Patent Literature 1 noted below discloses an example of a method for manufacturing the above-described magnetic head. Hereinafter, the method will be described briefly and a part of the manufacturing method is shown in FIG. 8.

A wafer W, in which magnetic head structures R each including the magnetic head slider part and the magnetic head element part are formed in matrix as shown in FIG. 8A, is cut into bars (referred to as “bar block B” hereinafter) each having a plurality of magnetic head structures R arranged in line. A surface (the surface facing the magnetic disk) of the bar block B is polished for providing an air bearing surface (ABS) for the magnetic head (the lower surface side of FIG. 8C). This polishing exposes the end face of the magnetoresistive element M to the air bearing surface (ABS) for sensitively detecting a week magnetic field from the magnetic disk and, at the same time, defines the element height Mh (MR height) of the magnetoresistive element in the vertical direction with respect to the polished surface (the air bearing surface) so as to obtain a prescribed resistance value.

FIG. 9 shows a fragmentary enlarged cross section of the magnetic head structure R. This illustration is a cross section taken almost at the center part of the magnetic head structure R in which the magnetoresistive element M is formed. Exposure of the end face of the magnetoresistive element M to the air bearing surface is not limited to be performed by the above-described polishing. It may be exposed when cutting the wafer W into the bar blocks B, and the element height Mh may be defined by polishing performed thereafter.

Conventionally, polishing of the bar block is generally performed mechanically and it is disclosed in Patent Literature 1.

After performing the polishing as described above, a resin is applied. Then, etching is performed for decreasing the roughness of the surface. Subsequently, a resist is applied and etched for forming the ABS in a prescribed shape. Then, a plurality of the magnetic head structures R integrated as the bar block B are cut into individual magnetic heads.

[Patent Literature 1] Japanese Patent Unexamined Publication 2004-71024

However, the etching process in the magnetic head manufacturing method disclosed in Patent Literature 1 is the process performed mainly for decreasing the roughness of the surface of the magnetic head. Therefore, conventionally, there has not been thoroughly investigated to deal with mechanical distortion that is generated in the bar block, i.e. inside the magnetic head structure, which is caused by the mechanical polishing and to deal with changes and deterioration of the property of the magnetoresistive element.

Furthermore, there may be a small margin in the height or the like of each magnetoresistive element M included in the individual magnetic head structure R within the bar block B generated at the time of laminating the thin films or cutting the wafer into the bar blocks B. Moreover, the surface forming processing on the bar block B may not be performed uniformly. In these respects, it is also clear that Patent Literature 1 does not consider how to define the element height Mh of the magnetoresistive element M uniformly with high precision in all the magnetic heads, since it is noted in Patent Literature 1 that the polishing is performed simultaneously to all the plurality of magnetic head structures R in the bar block B. Studies regarding these respects are essential since, for example, it is necessary for a Cpp-type magnetic head to define the element height of the magnetoresistive element with high precision such as 50 nm±5 nm.

### SUMMARY OF THE INVENTION

The object of the present invention therefore is to manufacture a uniform and high-quality structure which exhibits no quality changes due to mechanical process.

The surface forming method according to the present invention therefore is a surface forming method for performing surface forming process on a prescribed structural body, wherein the surface forming process is performed by irradiating, to the structural body, an energy beam with a prescribed energy, which can be irradiated to a specific direction.

With the above-described invention, the energy beam having a straight-traveling characteristic towards the structural body is irradiated for corroding the surface of the structural body, thereby allowing proper surface forming process to be performed. Since the surface forming process is performed without applying mechanical polishing, it is possible to manufacture the structural body having no quality changes due to the mechanical process, thereby enabling the structural bodies to be manufactured with higher quality. This is particularly effective for the precision components such as magnetic heads.

Further, the surface forming process is performed to a wafer containing a plurality of the structural bodies, and the surface forming method comprises the steps of: a structural body specifying step for specifying a structural body that requires no surface forming process based on a change in the structural body due to the surface forming process; and a shielding step for shielding the energy beam irradiated to the specified structural body.

In the above-described structure, particularly, the structural body is a magnetic head, and the surface forming process is performed to set element height of a magnetoresistive element that constitutes the magnetic head.

At this time, the structural body specifying step specifies the magnetic head based on a change in the element height of the magnetoresistive element due to the surface forming process. Specifically, the structural body specifying step specifies the magnetic head containing the magnetoresistive element when the element height of the magnetoresistive element reaches a reference height that is set in advance. The reference height may have a prescribed range.

Furthermore, the structural body specifying step specifies the magnetic head based on a change in a property of the magnetoresistive element due to the surface forming process. At this time, the structural specifying step detects a resistance value of the magnetoresistive element and specifies the magnetic head based on a change in the resistance value. Specifically, the structural body specifying step specifies the magnetic head containing the magnetoresistive element when the resistance value of the magnetoresistive element reaches a reference resistance value that is set in advance. The reference resistance value may have a prescribed range.

Further, the surface forming process is ended when the energy beam is shielded for all of the plurality of magnetic heads by the shielding step.

Furthermore, the magnetic head manufacturing method as another form of the present invention comprises the steps of: a cutting-out step for cutting out a wafer containing a plurality of magnetic heads; a surface forming step for performing surface forming process on the cut-out wafer by the surface forming method according to claim 3; an air bearing surface forming step for forming respective air bearing surfaces of the magnetic heads; and a separating step for separating the wafer into individual magnetic heads.

Moreover, as other forms of the present invention, a structural body or a magnetic head manufactured by using any of the above-described methods has surface forming process performed by irradiating an energy beam with a prescribed irradiation energy, which can be irradiated in a specific direction, wherein there is no quality changes caused due to mechanical process.

In the present invention of the above-described structure, first, the energy beam is irradiated to the wafer having a plurality of the structural bodies formed integrally in order to apply the surface forming process and, at that time, the structural body that no longer requires the surface forming process is specified. For example, in the case where the structural body is the magnetic head and the surface forming process is performed to define the height of the magnetoresistive element, the structural body that no longer requires the surface forming process is specified based on the changes in the height of the magnetoresistive element or the property (for example, the resistance value) thereof. Then, irradiation of the energy beam to the specified structural body is shielded. With this, the surface forming process is not performed thereafter on the specified structural body, which is maintained in the state where the proper surface processing is completed. In the meantime, the surface forming process is still performed on other structural bodies. When it is judged in the same manner that the surface forming process is not necessary for other structural bodies either, the energy beam is shielded. Thereby, proper surface forming process is applied to the individual structural bodies, so that all the magnetic heads can be manufactured uniformly and with high quality.

At this time, detecting the resistance value of the magnetoresistive element and specifying the structural body to be shielded according to the resistance value provides easy judgment and improved precision. Thus, it becomes possible to manufacture the structural bodies with better uniformity and higher quality.

Further, the surface forming apparatus as another form of the present invention is a surface forming apparatus that comprises a surface forming device for performing surface forming process on a prescribed structural body, wherein the surface forming device is an irradiation device for irradiating, to the structural body, an energy beam with a prescribed irradiation energy, which can be irradiated in a specific direction.

The surface forming process is performed on a wafer containing a plurality of the structural bodies, and the surface forming apparatus comprises: a shielding device for shielding the irradiated energy beam by covering a surface-forming-processing surface of the structural body by each structural body; and a shielding control device for controlling a state of shielding by the shielding device based on a change in the structural body due to the surface forming processing.

Furthermore, the above-described structural body is a magnetic head, and the surface forming device performs the surface forming processing to set element height of a magnetoresistive element that constitutes the magnetic head.

Moreover, the surface forming apparatus comprises a detection device for detecting the element height of the magnetoresistive element by each magnetic head, wherein the shielding control device controls the shielding device to shield the energy beam irradiated to the magnetic head based on a value detected by the detection device.

Further, the surface forming apparatus comprises a detection device for detecting a change in a property of the magnetoresistive element by each magnetic head, wherein the shielding control device controls the shielding device to shield the energy beam irradiated to the magnetic head based on the change in a value detected by the detection device.

At this time, the detection device is a resistance value detection device for detecting a resistance value of the magnetoresistive element; and the shielding control device controls the shielding device to shield the energy beam irradiated to a specific magnetic head based on a change in the resistance value detected by the resistance value detection device.

Furthermore, at this time, the shielding control device controls the shielding device to shield the energy beam irradiated to the magnetic head containing the megnetoresistive element, when the resistance value detected by the resistance value detection device reaches a reference resistance value that is set in advance. The reference resistance value may have a prescribed range.

The surface forming apparatus with the above-described structure also functions like the above-described surface forming method, so that it can achieve the object of the present invention described above.

The present invention is formed and functions as described above. In the present invention, the surface forming process is performed by irradiating the energy beam without performing the mechanical surface forming process. Thus, it is possible to manufacture the structural body having no quality changes due to the mechanical process, which is an excellent effect that is not of the conventional case. Furthermore, shielding the irradiation of the energy beam to the individual structural bodies provides the proper surface forming process to the individual structural bodies. Therefore, it can achieve such an excellent effect that all the structural bodies can be polished uniformly with high quality, which is not of the conventional case.

### BRIEF DESCRIPTION OF THE DRAWINGS

FIG. 1 is a schematic diagram for showing the structure of a surface forming apparatus according to the present invention;

FIG. 2 is a functional block diagram for showing the structure of a controller according to a first embodiment;

FIG. 3 is an illustration for showing the state at the time of performing surface forming process by the surface forming apparatus according to the first embodiment;

FIG. 4 is an illustration for showing the state at the time of performing surface forming process by the surface forming apparatus according to the first embodiment, while being shielded by a shielding member;

FIG. 5 is a flowchart for showing the action of the surface forming apparatus according to the first embodiment;

FIG. 6 is a functional block diagram for showing the action of a controller according to a second embodiment;

FIG. 7 is a flowchart for showing the action of the surface forming apparatus according to the second embodiment;

FIGS. 8A, 8B, and 8C are illustrations for describing, respectively, the states when cutting out a bar block including a magnetic head structure; and

FIG. 9 is a fragmentary enlarged cross section for showing the structure of a magnetic head element part of the magnetic head structure.

### DETAILED DESCRIPTION OF THE PREFERRED EMBODIMENT

The present invention is distinctive in respect that the surface forming process for the structural body is not performed by mechanical polishing but by irradiation of energy beams. Furthermore, when performing the surface forming process collectively on a plurality of structural bodies, the energy beams are shielded by each structural body in accordance with the state of the surface forming process to be performed on the individual structural bodies. In the followings, there will be described the structures of the surface forming method, the surface forming apparatus and the like of the present invention by referring to the case where a magnetic head that reproduces data from a hard disk mounted to a hard disk drive (HDD) is the structural body as a target of the surface forming process. However, the structural body as a target of the surface forming process in the present invention is not limited to the magnetic head.

### First Embodiment

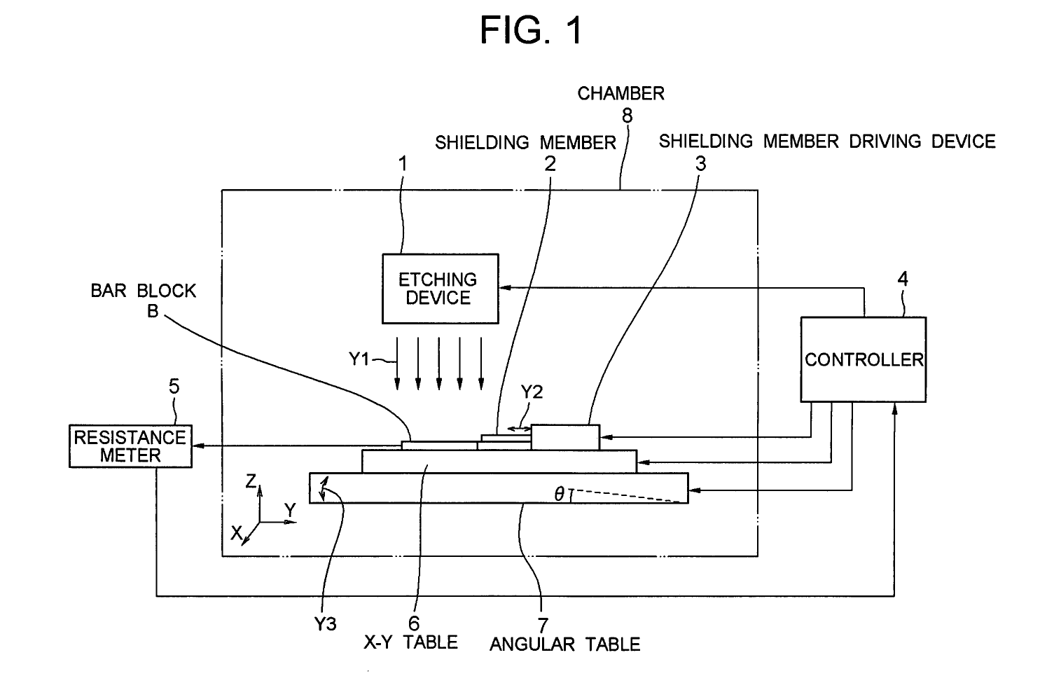

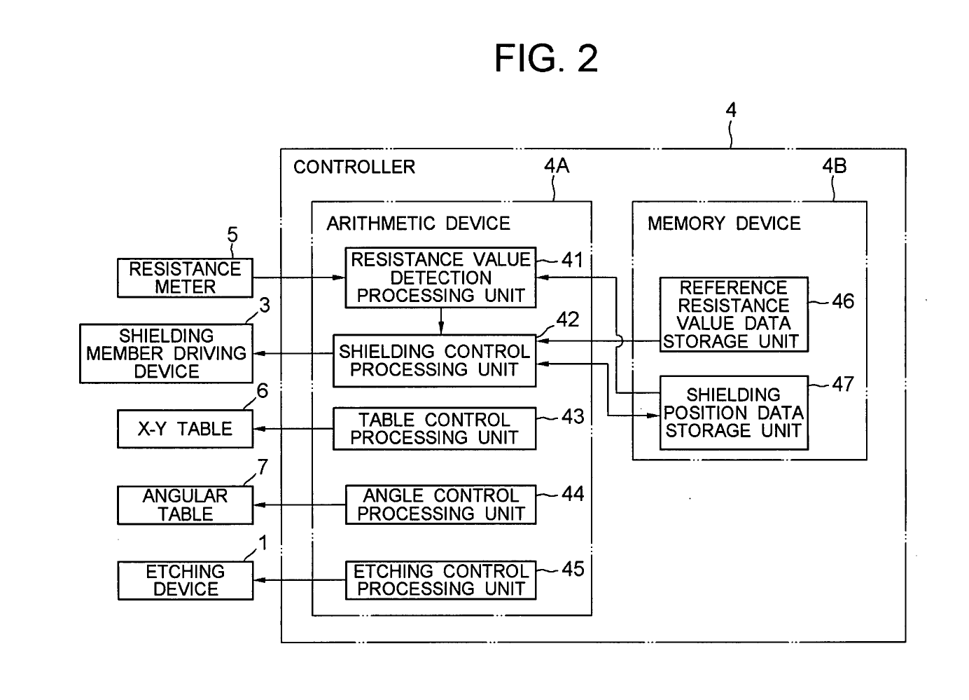

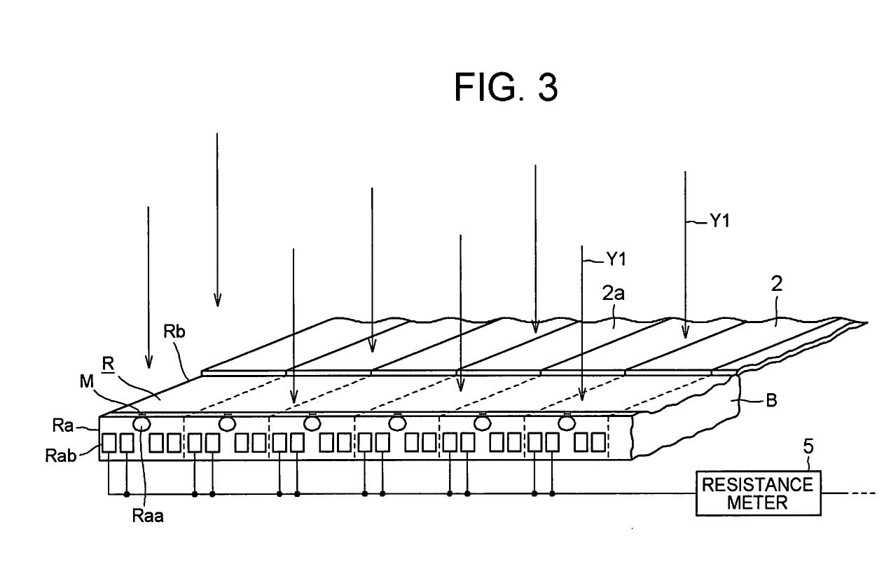

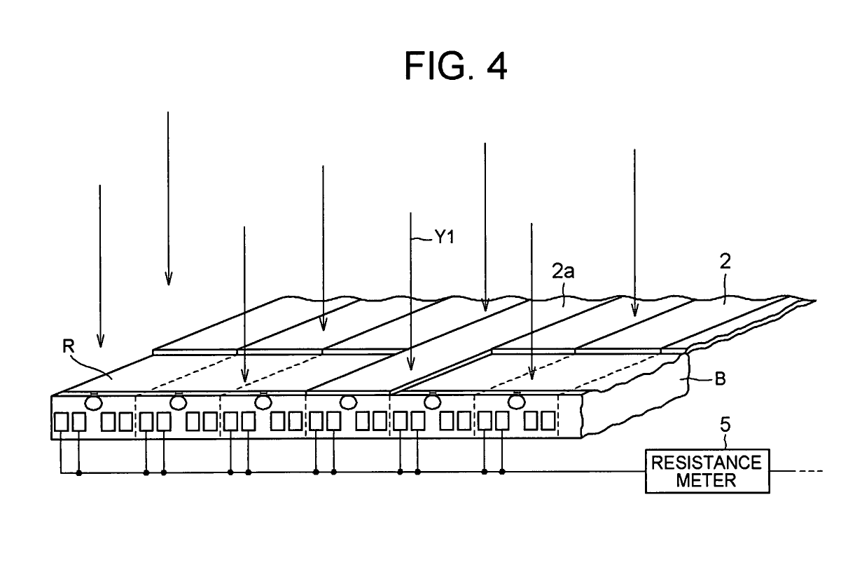

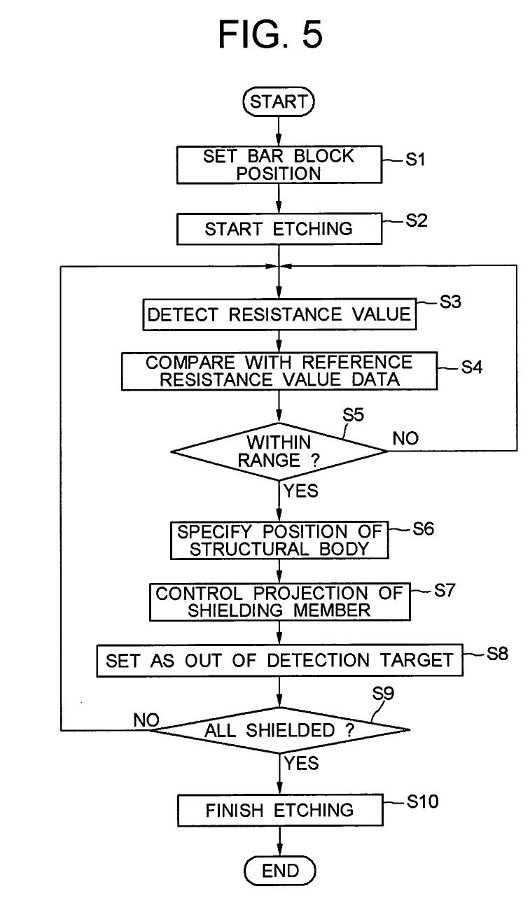

A first embodiment of the present invention will be described by referring to FIG. 1-FIG. 5. FIG. 1 is a block diagram for showing the structure of the surface forming apparatus. FIG. 2 is a functional block diagram for showing the structure of a controller. FIG. 3 and FIG. 4 are illustrations for describing the state of the magnetic head at the time of surface forming process. FIG. 5 is a flowchart for showing the surface processing action.

[Structure]

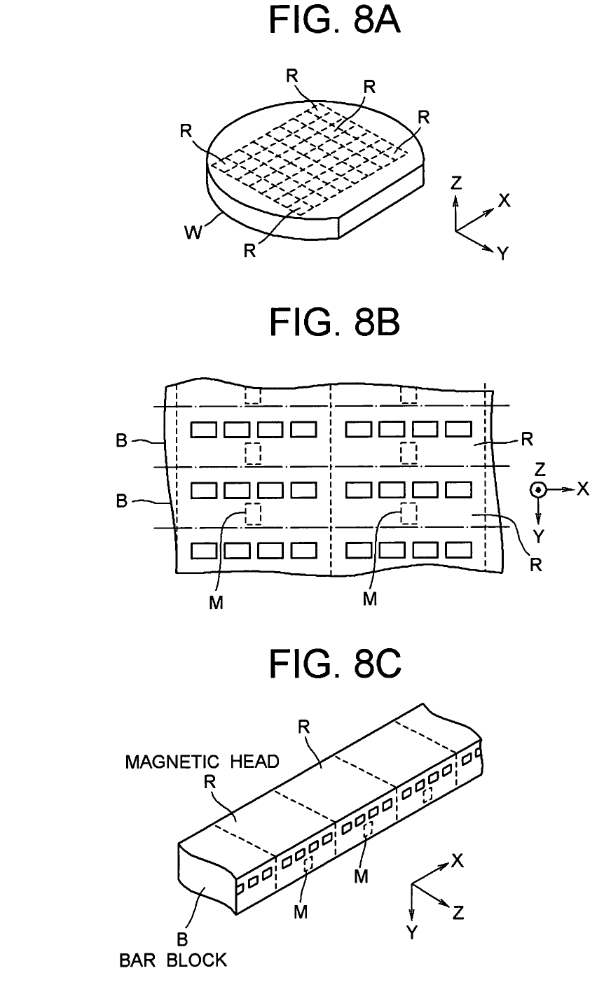

As shown in FIG. 8 and described as the related art, the surface forming apparatus according to the present invention is an apparatus that performs surface forming processing, e.g. etching an air bearing surface on a bar-type block (bar block B) in which magnetic heads R are arranged in line, i.e. a wafer W including a plurality of magnetic heads R. Thus, the surface forming apparatus constitutes a part of a magnetic head manufacturing apparatus.

As shown in FIG. 1, the surface forming apparatus according to the embodiment comprises: an etching device 1 (surface forming device) for performing surface forming process by etching the bar block B that includes a plurality of magnetic heads R as the targets of the surface forming process; a shielding device 2, 3 for shielding the etching by covering the surface to be polished by each magnetic head in the bar block B; and a controller 4 (shielding control device) which controls the state of shielding by the shielding device 2, 3 based on changes in the magnetic head R due to the surface forming process. Furthermore, the surface forming apparatus comprises: a resistance meter 5 (resistance value detecting device) which detects the resistance value of magentoresistive element M of the magnetic head R at the time of the surface forming process and informs it to the controller 4; an X-Y table 6 for setting the position of the bar block B by having the bar block placed thereon and driving it along the placing face; an angular table 7 for setting the etching angle of the bar block B by having the X-Y table 6 placed thereon; and a chamber 8 that provides an environment for performing etching by the etching device 1. Each structure will be described in detail hereinafter.

(Magnetic head)

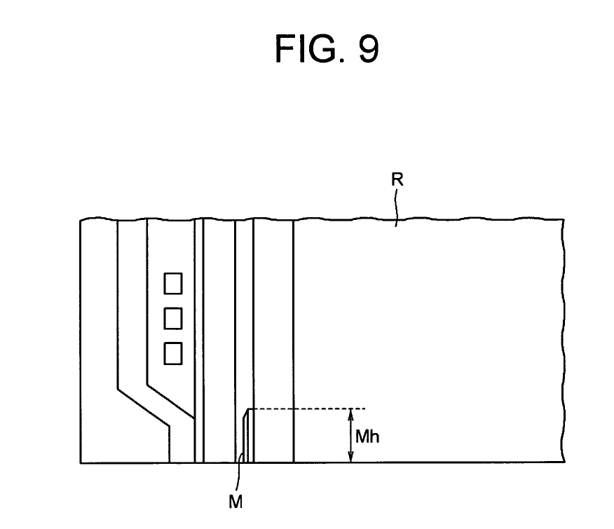

As described above, the magnetic head R is the same as that shown in FIG. 8 and FIG. 9. At the time of the surface forming process, a plurality of the magnetic heads R are arranged in line into the bar block B. The magnetic heads R are cut later at broken lines shown in FIG. 8C and FIG. 3 to produce individual magnetic heads. Therefore, each magnetic head R is formed comprising a magnetic head slider part Rb that mainly constitutes the main body of the magnetic head and, at one end thereof, a magnetic head element part Ra having a data recording/reproducing part Raa and a connecting terminal Rab. The data recording/reproducing part Raa is provided with the magnetoresistive element M (MR element) to be used for reproducing data as described above (see FIG. 9), which is exposed to the air bearing surface side (on the upper side of FIG. 3 and FIG. 4) and defined to a prescribed element height Mh (MR height) by the surface forming process.

(Etching Device)

The action of the etching device 1 is controlled by the controller 4. The etching device 1 is a device which, for example, performs etching within the chamber 8 in vacuum, polishes the air bearing surface of the magnetic head R, sets the thickness of the magnetic head itself, and defines the element height Mh of the magnetoresistive element M. The etching device 1 of the embodiment performs ion beam etching by irradiating ion beams to the magnetic head R (see arrows Y1 of FIG. 3).

However, the etching device 1 is not limited to be the apparatus that performs ion beam etching by irradiating ion beams. It may be any device as long as it irradiates energy beams (for example, electron beams, laser beams, etc.), which has a prescribed irradiation energy and can be irradiated in a specific direction. Therefore, etching in the present invention means the process for eroding the surface of the structural body R by irradiation energy of the energy beams by a method other than the mechanical polishing. The structure of the shielding member 2 to be described later differs depending on the types of the energy beams used for etching. It will be described later.

(Shielding Device)

The shielding device 2, 3 is constituted of a shielding member 2 and a shielding member driving device 3 for driving the shielding member 2. The shielding member 2 is roughly a plate-type member that is divided for corresponding to each magnetic head R included in the bar block B as shown in FIG. 3 and FIG. 4. Specifically, it is arranged along the air bearing surface of the magnetic head R and a divided shielding member 2 is formed to have the width of each magnetic head R. There are the shielding members 2 for at least the number of all the magnetic heads R that constitute the bar block B, which are uniformly arranged along the bar block B. In this state, positional information for identifying the shielding member 2 is applied to the shielding members. For example, they are numbered 1, 2, 3 and so on from the left end of FIG. 3. When placing the bar block B on the X-Y table 6, the bar block B is placed in such a manner that the magnetic head R comes essentially at the left end of the shielding member 2, so that the identifying information of the magnetic head R that is informed from the resistance meter 5 as will be described later corresponds to the positional information of the shielding member 2.

Further, one end of the shielding member 2 (the end that is not shown in FIG. 3 and FIG. 4) is supported by the shielding member driving device 3 placed on the X-Y table 6 to be described later. The shielding member driving device 3 is formed to be capable of driving each shielding member 2 supported thereby towards the air bearing surface of the magnetic head, respectively, i.e. in the direction of projecting towards the etching surface (see an arrow Y2 in FIG. 1). Thus, when the shielding member 2 shown by a reference numeral 2a in FIG. 3 is driven by the shielding member driving device 3 to be projected, it is projected over the magnetic head R positioned underneath for covering the etching surface as the air bearing surface. Specifically, the shielding member 2 is arranged on the irradiation path of the energy beams such as ion beams irradiated by the etching device 1. Thereby, irradiation of the energy beams on the air bearing surface of the magnetic head R can be shielded properly.

The above-described shielding member 2 is not limited to be the plate type. Further, the shape and the material are selected at will as long as, as described above, irradiation of the energy beams to the air bearing surface of the magnetic head R can be shielded properly when it is projected over the magnetic head R.

The drive-control of the shielding member 2 by the shielding member driving device 3 is performed by the controller 4 based on the resistance value detected by the resistance meter 5 to be described later. The shielding member driving device 3 drive-controls a specific shielding member 2 based on the positional information of the shielding member 2 indicated by the controller 4.

(Table)

The X-Y table 6 has the bar block B including a plurality of the above-described magnetic heads R directly placed thereon, and moves along the placing face for bringing the bar block B beneath the etching device 1. In other words, it is a device for setting the bar block B at a position where it can be etched. In FIG. 1, the structure for driving the X-Y table 6 is not illustrated, however, it is provided with a structure capable of moving on the X-Y plane while having the bar block B placed thereon.

Further, the angular table 7 is for placing the X-Y table 6 itself with the bar block B disposed thereon to set the angle thereof. For example, when performing ion beam etching, the angular table 7 sets the angle of the etching surface of the magnetic head R with respect to the irradiated ion beams for enabling the effective etching processing. That is, the magnetic head slider part Rb of the magnetic head R is formed of Al-Tic and the magnetic head element part Ra is formed of a metal such as Cr, Ni, so that each part has different removal rate by etching. Thus, for enabling proper etching, the irradiation angle of the ion beams with respect to the magnetic head R is set by using the angular table 7. For example, the angular table 7 is movable within the range of θ (between −80° and +80°) as shown by arrows Y3.

(Resistance Meter)

The resistance meter 5 detects the resistance value of each magnetoresistive element M that constitutes the individual magnetic head R included in the bar block B. Thus, as shown in FIG. 3, the data-reproduction connecting terminal Rab in each magnetic head R has wirings each for detecting the resistance connected to the resistance meter 5. The resistance value of each magnetoresistive element M detected by the resistance meter 5 is informed to the controller 4. Since the wirings for each magnetoresistive element M are connected to the resistance meter 5, the resistance meter 5 can detect the resistance value by discriminating the magnetoresistive element M, i.e. by determining which magnetic structural body the resistance value belongs to, based on the wiring from which the resistance value is detected. Therefore, the resistance meter 5 informs the identifying information for specifying the magnetic head R as the detection target to the controller 4 together with the detected resistance value. In the bar block B shown in FIG. 3, for example, the identifying information is numbered 1, 2, 3 and so on from the magnetic head R positioned at the left end towards the right side. In other words, it is the information corresponding to the positional information numbered in the above-described shielding members 2. In the above-described case, the same numbers are applied to the magnetic head R and the corresponding shielding member 2.

Measurement of the resistance value is continuously carried out while the ion beam etching is performed on the magnetic head R. That is, it is carried out to detect changes in the resistance value, which occur in accordance with changes in the element height Mh of the magnetoresistive element M when the air bearing surface is corroded by the etching.

For the detected resistance value, there are appropriate resistance values (“reference resistance values” which will be described later) depending on the magnetic structural bodies R, which are found in advance experimentally or theoretically. The value is monitored by the controller 4 to check whether it has reached such value as will be described later. The above-described reference resistance value may be the resistance value when the element height Mh becomes a proper height.

(Controller)

The controller 4 comprises an arithmetic device 4A such as a CPU and a memory device 4B such as a ROM capable of holding stored data and rewriting the data.

In the memory device 4B, there is formed a reference resistance value data storage unit 46 for storing the reference resistance value that is compared to the resistance value measured by the resistance meter 5. As described above, the reference resistance value is the pre-defined resistance value by an experiment or the like with which data can be reproduced properly, or the resistance value when the element height becomes a proper height (for example, 100 nm±17 nm). The reference value of the embodiment is set with a prescribed range (for example, set as 100Ω±5Ω, etc). However, the reference resistance value is not limited to be set with a prescribed range but may be specified as a certain value.

Further, in the memory device 4B, there is formed a shielding position data storage unit 47 for storing the positional information of the shielding member 2 that has already been at the position for shielding. As will be described later, the shielding position data storage unit 47 stores the positional information of the shielding member 2 after the shielding control is performed.

A prescribed program is installed in advance to the arithmetic device 4A, thereby building: a resistance value detection processing unit 41 for detecting the resistance value from the resistance meter 5; a shielding control processing unit 42 for controlling the shielding state of the shielding member 2 through controlling the shielding member driving device 3; a table control processing unit 43 for controlling the action of the X-Y table 6; an angle control processing unit 44 for controlling the action of the angular table 7; and an etching control processing unit 45 for controlling the action of the etching device 1. Each of the processing units 41-45 will be described in detail hereinafter.

The resistance value detection processing unit 41 receives the resistance values of each magnetoresistive element M for every magnetic heads R, which are detected by the resistance meter 5 during the etching processing. At this time, along with the resistance values, it receives from the resistance meter 5 the identifying information for specifying the magnetic head R from which the resistance value is outputted. The resistance value detection processing unit 41 informs the detected resistance value along with the identifying information that specifies the magnetic head R (magnetoresistive element M) as the detection target to the shielding control processing unit 42.

The resistance value detection processing unit 41 refers to the positional information of the shielding member 2 being used as a shield, which is recorded in the shielding positional data storage unit 47, and cancels the resistance value detected from the magnetic head R that corresponds to the shielding member 2 being used as the shield. Alternatively, it gives a command to the resistance meter 5 not to detect the resistance value from the magnetic head R that is being shielded. With this, the processing can be sped up by eliminating the processing for the magnetic head R that has already been shielded. At this time, for example, the magnetic head R with the identifying information of the same number as that of the stored positional information is specified as the magnetic head R that corresponds to the positional information of the shielding member 2 stored in the shielding positional data storage unit 47.

Further, the shielding control processing unit 42 reads out the reference resistance value from the reference resistance value data storage unit 46 and compares it to the resistance value informed from the resistance value detection processing unit 41 for checking whether or not the detected resistance value is within the range of the reference resistance value. When it is within the range, a driving command is outputted to the shielding member driving device 3 to drive to shield the etching for the magnetic head R as the detection target by the shielding member 2. Specifically, the shielding control processing unit 42 specifies the positional information of the shielding member 2 that corresponds to the identifying information of the magnetic head R and outputs a command to the shielding member driving device 3 to drive to project the shielding member 2. Then, the positional information of the projected shielding member 2 is stored in the shielding positional data storage unit 47 of the memory device 4B so that, as described above, the resistance value detection processing unit 41 can refer thereto. The shielding member 2 to be projected is the shielding member 2 with the positional information of the same number as that of the identifying information of the magnetic head R whose resistance value is detected as being within the reference resistance value, for example.

Further, the etching control processing unit 45 controls the action of the etching device 1 for starting or stopping the irradiation action of ion beams and controls the intensity of the ion beams. Furthermore, the table control processing unit 43 controls the driving state of the X-Y table 6 along the X-Y plane so as to control the position of the bar block B (magnetic head R) placed on the X-Y table such that the ion beams from the etching device 1 can be properly irradiated. Moreover, the angle control processing unit 44 controls the irradiation angle of the ion beams from the etching device 1 with respect to the bar block B (magnetic head R) placed through the X-Y table 6 to be set at an angle by which a proper etching can be achieved.

(Operation)

Next, a polishing operation by the above-described surface forming apparatus will be described and a magnetic head manufacturing method including the polishing operation as one step will be described as well. FIG. 3 and FIG. 4 are illustrations for describing the state of the magnetic head R at the time of polishing, and FIG. 5 is a flowchart for showing the polishing operation.

First, as shown in FIG. 8, from the wafer W in which the magnetic head element part Ra is lamination-formed and a plurality of magnetic heads R are formed in matrix, the bar block B with the magnetic heads R arranged in line is cut out (a cutting-out step, not shown). Then, the surface forming processing is performed on the bar block B (a surface forming step).

In the surface forming step, first, the bar block B is placed on the X-Y table 6, and the X-Y table 6 is driven to be set at a position where etching can be properly performed on the etching surface of the bar block B (magnetic head R) from the etching device 1 (step S1). At the same time, the angle θ of the angular table 7 is driven as well for setting the angle to be appropriate for the ion beams to carry out the etching (step S1). The position setting operations by each of the tables 6 and 7 may be performed during the etching.

After completing the position setting of the magnetic head R described above, irradiation of the ion beams by the etching device 1 is started (step S2). Upon this, as shown in FIG. 3, the ion beams are irradiated to the etching surface of each magnetic head R constituting the bar block B (see arrows Y1). Thereby, the surface forming processing of the etching surface is performed and the element height Mh of the magnetoresistive element M of each magnetic head R is set.

During the etching, the respective resistance values of each magnetic head R are detected by the resistance meter 5, which are collected in the controller 4 (step S3). The controller 4 then compares the detected resistance value and the reference resistance value stored in the reference resistance value data storage unit 46 (step S4), and checks whether or not the detected value is within the range of the reference resistance values (step S5). As a result of comparison, when it is determined that the detected resistance value is not within the range of the reference resistance value (NO in step S5), the etching processing is continued and detection of the resistance value is also performed continuously (step S3).

In the meantime, when it is determined in the step S5 that the resistance value is within the range of the reference resistance value (YES in step S5), the magnetic head R no longer requires the surface forming processing. Thus, the magnetic head R is specified (a structural body specifying step), and the ion beams for the magnetic head is shielded (a shielding step). Specifically, there is specified the positional information of the shielding member 2 that corresponds to the identifying information of the magnetic head R received from the resistance meter 5 along the resistance value (step S6). By way of example, specified is the positional information with the same number as that of the identifying information of the magnetic head R. Then, a driving command is outputted to the shielding member driving device 3 to project the shielding member 2 by designating the specified positional information. Upon this, the shielding member driving device 3 projects the shielding member 2 to which the designated positional information is allotted so as to cover over the magnetic head R (step S7). For example, when the resistance value detected from the magnetic head R positioned underneath the shielding member denoted by the reference numeral 2a in FIG. 3 is within the range of the reference resistance value, only the shielding member denoted by the reference numeral 2a positioned over the magnetic head R is projected as shown in FIG. 4.

With this, ion beams are shielded by the shielding member 2 and the etching of the magnetic head R positioned thereunder can be intercepted. Therefore, the element height Mh of the shielded magnetic head R is set at the detected resistance value. Even in that case, ion beams are still irradiated to other magnetic heads R on the bar block B as shown in FIG. 4, so that the etching is continuously performed.

After performing the shielding control for the specific magnetic head R, it is so set that the magnetic head R is eliminated from the target of detecting the resistance value (step S8). For example, the positional information of the shielding member 2 corresponding to the shielded magnetic head R is registered to the shielding position data storage unit 47. The resistance value detected from the magnetic head R to which the identifying information corresponding to the registered positional information is allotted is not compared to the reference resistance value data thereafter or the detection processing itself is not executed.

Then, the positional information of the shielding member which has already been used as a shield and is stored in the shielding positional data storage unit 47 is referred to check whether or not the shielding control is executed on all the magnetic heads of the bar block B (step S9). When there remains the magnetic head R to which the etching is still performed (NO in step S9), it returns to the step S3 where detection of the resistance value is continued and shielding is performed based on the resistance value. When the shielding of the etching is performed to all the magnetic heads R (YES in step S9), the etching processing is ended (step S10).

With this, etching processing can be executed to the individual magnetic heads R that are integrally present on the bar block B so that the respective element height of each magnetoresistive element can be set appropriately. Thus, it is possible to perform the uniform and high-quality surface forming processing on all the magnetic heads R.

Subsequently, processing for forming an air bearing surface (an air bearing surface forming step) is performed on the bar block B (magnetic head R) to which the surface forming processing has been completed. In the air bearing surface forming step, for example, a resist is formed on a prescribed surface to which the air bearing surface of the magnetic head R is formed, and etching is performed on that surface. Then, this processing is repeated for a plurality of cycles for forming a complicated air bearing surface with a plurality of steps.

Then, the individual magnetic heads R are separated from the bar block B (a separating step). Thereby, individual magnetic heads can be produced.

In this state, the produced magnetic head has received the surface forming processing by etching but not the mechanical surface forming processing at the time of the surface forming processing as described above. Thus, it is possible to manufacture the magnetic head having no quality changes due to mechanical processing. Therefore, it is possible to achieve still higher quality.

In the above, the case of detecting the resistance value of the magnetoresistive element M has been described as a way of example. However, other properties different from the resistance value of the magnetoresistive element M may be detected. Then, the shielding member 2 may be controlled in the same manner as described above to shield the magnetic head R that is determined based on the detected values that it no longer requires the surface forming processing.

### Second Embodiment

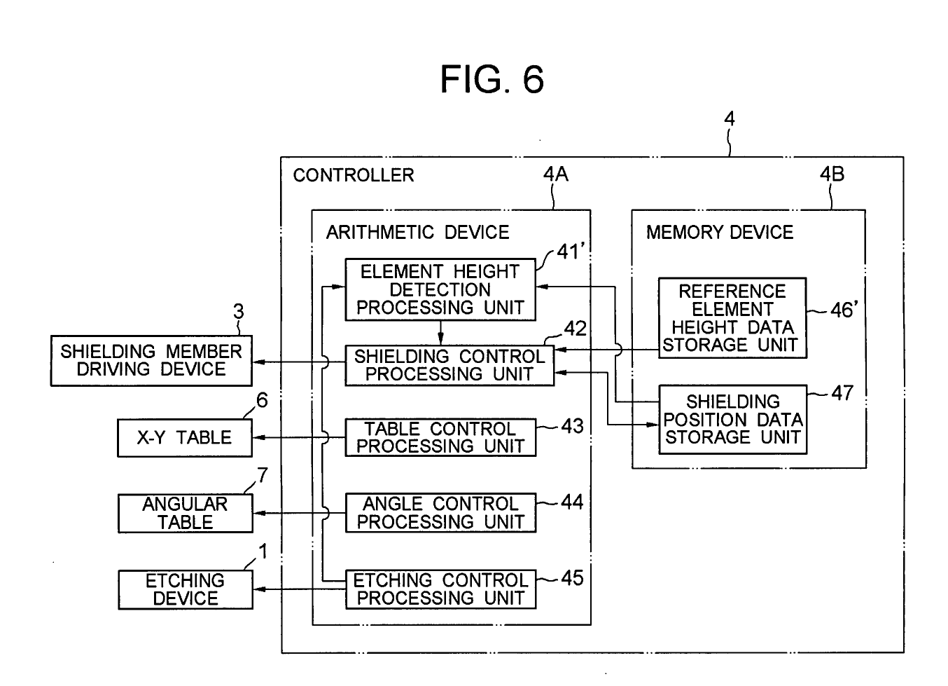

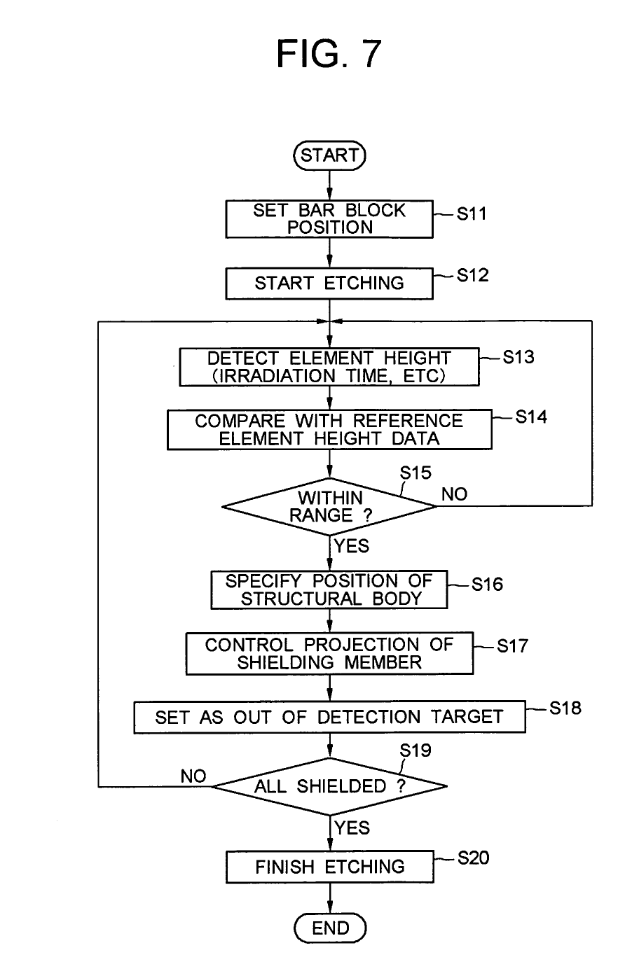

Next, a second embodiment of the present invention will be described by referring to FIG. 6 and FIG. 7. FIG. 6 is a functional block diagram for showing the structure of a controller of a surface forming apparatus according to the embodiment. FIG. 7 is a flowchart for showing the action of the surface forming apparatus according to the embodiment.

Basically, the surface forming apparatus of the embodiment employs almost the same structure as that of the surface forming apparatus described in the first embodiment. However, it is different in terms of the structure for judging the timing of shielding the energy beams by driving the shielding member 2. That is, in the above-described first embodiment, shielding is performed based on the resistance value of the magnetoresistive element M of the magnetic head R. However, in this embodiment, the element height Mh of the magnetoresistive element M is detected and the shielding action is controlled in accordance with the changes thereof. In the followings, the structure exhibiting such characteristic will be described in detail.

(Structure)

Basically, the controller 4 of the surface forming apparatus according to the second embodiment employs almost the same structure as that of the first embodiment described above (see FIG. 2). However, as shown in FIG. 6, an element height detection processing unit 41′ is built in the arithmetic device 4A. Furthermore, a reference element height storage unit 46′ is formed in the memory device 4B.

During etching, the above-described element height detection processing unit 41′ detects the irradiation time of the ion beams by the etching control processing unit 45. In other words, the element height Mh of the magnetoresistive element M is shortened in accordance with the irradiation time of the ion beams. Thus, the element height Mh is indirectly detected by detecting the irradiation time.

Further, the reference irradiation time of the ion beams that can define the appropriate element height Mh is stored in the reference element height data storage unit 46′. In other words, there is stored the data of the reference irradiation time which indirectly shows the element height to be set. In that state, different reference irradiation time is set in accordance with the positions of each magnetic head R on the bar block B. In short, there are a plurality of sets of reference irradiation time set for corresponding to each position, and respective positional information is added thereto so that each can be identified. Since the intensity of the ion beams irradiated to the bar block B differs in accordance with the position (for example, there may be a case where the irradiation intensity for the magnetic head R positioned at the end of the bar block B is weaker than that of the irradiation beams for the one in the center), the reference irradiation time is set in advance considering such condition. The reference irradiation time data is expressed with a prescribed range, which is set in accordance with the allowable range of the element height Mh. The positional information applied for each reference irradiation time described above is the information to which the same number as that of the position of each shielding member 2 is applied, for example.

Further, the shielding control processing unit 42 according to the embodiment judges whether or not the detected irradiation time is within the reference irradiation time data at a certain position, which is stored in the reference element height data storage unit 46′. When it is judged as being within the range, the shielding member 2 of the corresponding position is controlled to project as in the case of the first embodiment as described above.

(Operation)

Next, among the operations of the surface forming apparatus in the above-described structure, the surface forming step will be described by referring to FIG. 7. First, like the above-described case, the bar block B is placed on the X-Y table, and position setting on the X-Y table 6 and setting of the angle θ by the angular table 7 are carried out (step S11). Then, irradiation of the ion beams is started by the etching device 1 (step S12). Upon this, as shown in FIG. 3, the ion beams are irradiated to the etching surface of each magnetic head that constitutes the bar block B. Thus, the etching surface is corroded and the element height Mh of the magnetoresistive element M of each magnetic head R is defined.

During the etching, the irradiation time of the ion beams is detected by the element height detection processing unit 41′ (step S13). The detected irradiation time is compared to the reference irradiation time which is set for each magnetic head R and stored in the reference element height data storage unit 46′ (step S14). As a result of the comparison, when the detected irradiation time is not within the range of the reference irradiation time (NO in step S15), the etching process is continued and detection of the irradiation time is also continued (step S13).

In the meantime, when it is determined in the step S15 that the detected irradiation time is within the range of the reference irradiation time at a specific position (YES in step S15), the magnetic head R disposed at that position no longer requires the surface forming processing. Thus, the magnetic head R is specified (a structural body specifying step, step S16), and the ion beams for the magnetic head R is shielded (a shielding step, step S17). Specifically, there is specified the position of the magnetic head R which has received irradiation of the ion beams for an appropriate irradiation time based on the positional information contained in the reference irradiation time, and the shielding member 2 corresponding to that position is controlled to be projected.

Thereby, the ion beams are shielded by the projected shielding member 2a and etching of the magnetic head R positioned thereunder is intercepted. Therefore, the shielded magnetic head R has the defined element height Mh that is set by the irradiation intensity and irradiation time of the ion beams, which are set in advance. Even in that case, ion beams are still irradiated to other magnetic heads R on the bar block B, so that the etching is continuously performed.

After performing the shielding control for the specific magnetic head R, as in the above-described case, it is so set that the already shielded position is eliminated from the target of judging for shielding (step S18). The processing is continued until the shielding control is carried out for all the magnetic heads R on the bar block B (steps S19, S20).

In the above, there has been described by referring to the case where the element height during etching is detected by detecting the irradiation time and irradiation intensity of the ion beams. However, the element height Mh may be detected by other methods.

### Third Embodiment

Next, a third embodiment of the present invention will be described. The embodiment is distinctive in respect that the above-described timing of shielding is judged based on both the resistance value of the magnetoresistive element M and the irradiation time of the ion beams. In other words, the shielding action is controlled in accordance with the changes in the property of the magentoresistive element M and the element height Mh of the magnetoresistive element M during etching.

For example, as in the above-described first embodiment, the surface forming apparatus of the third embodiment detects the resistance value and compares it to the reference resistance value, and detects the irradiation time of the ion beams as well to compare it to the reference irradiation time. When a prescribed condition is satisfied, e.g. when either one is within the range of respective reference value or the both detected values are within the ranges of the respective reference values, the shielding member 2 is projected as described above for performing the shielding action of the ion beams.

Further, as in the above-described first and second embodiment, it is described that the irradiation direction of ion bean is from Y direction. However, the present invention is not only from Y direction, but also from Z direction (See FIG. 8C). In this case, the shielding member 2 is also arranged on the Z direction side (MR element forming surface or its opposing surface). By irradiating from Z direction, it is possible to settle the etching rate problem.

The present invention can be utilized as the polishing step that is performed when manufacturing magnetic heads, so that it has an industrial applicability.

What is claimed is:

1. A surface forming method for performing surface forming process on a prescribed structural body, wherein
said surface forming process is performed by irradiating, to said structural body, an energy beam with a prescribed energy, which can be irradiated to a specific direction.

2. The surface forming method according to claim 1, wherein
said surface forming process is performed on a wafer containing a plurality of said structural bodies, and
said surface forming method comprises the steps of: a structural body specifying step for specifying a structural body that requires no said surface forming process based on a change in said structural body due to said surface forming processing; and a shielding step for shielding said energy beam irradiated to said specified structural body.

3. The surface forming method according to claim 2, wherein
said structural body is a magnetic head, and
said surface forming process is performed to set element height of a magnetoresistive element that constitutes said magnetic head.

4. The surface forming method according to claim 3, wherein said structural body specifying step specifies said magnetic head based on a change in said element height of said magnetoresistive element due to said surface forming process.

5. The surface forming method according to claim 4, wherein said structural body specifying step specifies said magnetic head containing said magnetoresistive element when said element height of said magnetoresistive element reaches a reference height that is set in advance.

6. The surface forming method according to claim 5, wherein said reference height has a prescribed range.

7. The surface forming method according to claim 3, wherein said structural body specifying step specifies said magnetic head based on a change in a property of said magnetoresistive element due to said surface forming process.

8. The surface forming method according to claim 7, wherein said structural specifying step detects a resistance value of said magnetoresistive element and specifies said magnetic head based on a change in said resistance value.

9. The surface forming method according to claim 8, wherein said structural body specifying step specifies said magnetic head containing said magnetoresistive element when said resistance value of said magnetoresistive element reaches a reference resistance value that is set in advance.

10. The surface forming method according to claim 9, wherein said reference resistance value has a prescribed range.

11. The surface forming method according to claim 3, wherein said surface forming process is ended when said energy beam is shielded for all of said plurality of magnetic heads by said shielding step.

12. A magnetic head manufacturing method, comprising the steps of:
a cutting-out step for cutting out a wafer containing a plurality of magnetic heads;
a surface forming step for performing surface forming process on said cut-out wafer by said surface forming method according to claim 3;
an air bearing surface forming step for forming respective air bearing surfaces of said magnetic heads; and
a separating step for separating said wafer into individual said magnetic heads.

13. A structural body to which surface forming processing is performed by irradiating an energy beam with a prescribed irradiation energy, which can be irradiated in a specific direction, wherein there is no quality changes caused due to mechanical process.

14. A magnetic head manufactured by said magnetic head manufacturing method according to claim 12, wherein there is no quality changes caused due to mechanical process.

15. A surface forming apparatus, comprising a surface forming device for performing surface forming process on a prescribed structural body, wherein
said surface forming device is an irradiation device for irradiating, to said structural body, an energy beam with a prescribed irradiation energy, which can be irradiated in a specific direction.

16. The surface forming apparatus according to claim 15, wherein
said surface forming process is performed on a wafer containing a plurality of said structural bodies, and
said surface forming apparatus comprises: a shielding device for shielding said irradiated energy beam by covering a surface-forming-processing surface of said structural body by each said structural body; and a shielding control device for controlling a state of shielding by said shielding device based on a change in said structural body due to said surface forming process.

17. The surface forming apparatus according to claim 16, wherein
said structural body is a magnetic head, and
said surface forming device performs said surface forming to set element height of a magnetoresistive element that constitutes said magnetic head.

18. The surface forming apparatus according to claim 17, comprising a detection device for detecting said element height of said magnetoresistive element by each said magnetic head, wherein
said shielding control device controls said shielding device to shield said energy beam irradiated to said magnetic head based on a value detected by said detection device.

19. The surface forming apparatus according to claim 17, comprising a detection device for detecting a change in a property of said magnetoresistive element by each said magnetic head, wherein
said shielding control device controls said shielding device to shield said energy beam irradiated to said magnetic head based on said change in a value detected by said detection device.

20. The surface forming apparatus according to claim 19, wherein:
said detection device is a resistance value detection device for detecting a resistance value of said magnetoresistive element; and
said shielding control device controls said shielding device to shield said energy beam irradiated to a specific magnetic head based on a change in said resistance value detected by said resistance value detection device.

21. The surface forming apparatus according to claim 20, wherein
said shielding control device controls said shielding device to shield said energy beam irradiated to said magnetic head containing said megnetoresistive element, when said resistance value detected by said resistance value detection device reaches a reference resistance value that is set in advance.

22. The surface forming apparatus according to claim 21, wherein said reference resistance value has a prescribed range.
